(19) United States
(12) Patent Application Publication
(10) Pub. No.: US 2017/0016961 A1
(43) Pub. Date: Jan. 19, 2017

(54) METHOD FOR ASSESSING A STATE OF CHARGE OF A BATTERY COMPRISING A PLURALITY OF CELLS HAVING A VARIABLE RANGE OF USE OF STATE OF CHARGE

(71) Applicant: RENAULT s.a.s., Boulogne-Billancourt (FR)

(72) Inventor: Marc LUCEA, Versailles (FR)

(73) Assignee: RENAULT s.a.s., Boulogne-Billancourt (FR)

(21) Appl. No.: 15/124,295

(22) PCT Filed: Mar. 9, 2015
(86) PCT No.: PCT/FR2015/050566

§ 371 Date: Sep. 7, 2016

(30) Foreign Application Priority Data
Mar. 7, 2014 (FR) 1451892

(51) Int. Cl. G01R 31/36; B60L 11/18

(52) U.S. Cl. CPC G01R 31/3651; G01R 31/3658; G01R 31/3679; G01R 31/3675; B60L 11/1862

(57) ABSTRACT

A method assesses a state of charge of a battery including a plurality of electrochemical cells connected in series that each have a state of charge held between a minimum allowable state of charge value and a maximum allowable state of charge value. The method includes determining, at a given moment, the minimum cell voltage and the maximum cell voltage from the voltages at terminals of the cells, calculating a minimum state of charge of the cell having the minimum cell voltage and a maximum state of charge of the cell having the maximum cell voltage, and adjusting the minimum allowable state of charge value and the maximum allowable state of charge value of each cell depending on at least one physical quantity representative of a state of health of the cell and/or depending on a temperature of the battery.

### FIELD OF THE INVENTION

The invention relates to a method and a system for assessing the state of charge of a battery comprising a plurality of electrochemical cells connected in series.

This invention can be applied irrespective of the type of battery and extends, non-exclusively, to vehicles. In particular, the invention can be applied particularly in industrial sectors such as the automotive and computing sectors; the invention is applicable for any system, whether on-board or not.

### PRIOR ART

In the non-limiting field of electric and hybrid vehicles, one of the main challenges of traction battery management systems is that of assessing the state of charge of the battery, also referred to as the SOC. This information is displayed on the instrument panel in the form of a “battery gauge” and allows the driver to know the remaining autonomy in kilometers. Because the autonomy of an electric vehicle is much lower than that of a combustion-powered vehicle, it is important to reassure the driver by providing him with the most reliable information possible. Errors in the assessment of the battery gauge can indeed result in the driver finding himself in unfavorable situations (empty fuel tank), or even dangerous situations (loss of power when overtaking).

Nowadays, the state of charge SOC_{pack} of a battery comprising N electrochemical cells Cᵢ (where i is an integer between 1 and N) connected in series is assessed conventionally on the basis of measurements relating to the battery considered as a whole. Thus, a first piece of equipment measures the total voltage U_{BAT} delivered by the battery, measured at the terminals of the totality of the cells in series, and current and temperature sensors measure, respectively, the current I_{BAT} passing through the battery and the temperature T_{BAT} of the battery. On the basis of these three measurements a software unit calculates an assessment of the state of charge SOC_{pack} using a conventional method, such as an ampere-hour counting method, or a modeling of the Kalman filtering type. An assessment of this type based on overall measurements thus corresponds roughly to an average of the state of charge of the cells.

The electrochemical cells forming the battery, on account of their construction, have characteristics that differ from one another in terms of distribution of their capacity and of their internal resistance, and in addition experience different temperature variations as a result of their placement in the battery. Consequently, these cells necessarily have states of charge which differ from one another, which is why the battery is said to be imbalanced. When this is the case, the range of use of the battery is set by the cell charged to the greatest extent and by the cell charged to the lowest extent. In this case, the assessment based on overall measurements is false.

Further envisaged assessment devices recommend assessing the state of charge of each cell individually so as to deduce therefrom a state of charge value for the battery by taking into consideration the imbalance of the cells. A device of this type ideally comprises a first piece of equipment measuring, simultaneously, the voltages U₁ to U_{N} at the terminals of each cell Cᵢ forming the battery, a current sensor respectively measuring the current I_{BAT} passing through the N cells of the battery, and temperature sensors providing the temperature Tᵢ of each cell Cᵢ forming the battery. On the basis of each measurement Uᵢ, Tᵢ and I_{BAT}, N software units calculate an assessment of the state of charge SOCᵢ of each cell Cᵢ by using a conventional method such as an ampere-hour counting method, or a modeling of the Kalman filtering type. The state of charge SOC_{pack} of the battery is then assessed by a calculation module on the basis of the N states of charge SOCᵢ delivered by the software units. These devices are certainly more accurate, but are also more expensive and more complex in terms of software. They require voltage measurements at the terminals of each of the cells forming the battery and advanced models in order to describe the behavior of each cell (Kalman filtering in particular). In the case of a high-voltage battery, such as cells used for an electric vehicle, the large number of elementary cells (96 bi-cells in modern batteries) makes the cost of the device significant.

Lastly, in this field, a method is known for assessing a state of charge of a battery in which, on the basis of assessments relating to a maximum state of charge SOCₘₐₓ of the cell charged to the greatest extent and relating to a minimum state of charge SOCₘᵢₙ of the cell charged to the lowest extent, it is possible to reconstruct the state of charge SOC_{pack} of the battery; the value of the state of charge SOC_{pack} tends toward 0 when the minimum state of charge SOCₘᵢₙ tends toward 0, and toward 1 when the minimum state of charge SOCₘₐₓ tends toward 1. A method of this type is disclosed by the applicant in FR2990516. It has been noted that this method was not optimal, because it uses a minimum allowable state of charge value BSOCₘᵢₙ and a maximum allowable state of charge value BSOCₘₐₓ which are fixed, which makes it impossible to hold the maximum amount of energy stored in the battery at a constant value, in particular regardless of the state of aging of the cells. For the user, the variability of the maximum amount of stored energy is detrimental because it can result in unfavorable situations, such as an empty fuel tank or a loss of power during overtaking: these situations would be caused by a poor assessment of the state of charge of the battery.

### OBJECT OF THE INVENTION

In this context, the object of the invention is to overcome the disadvantages of the prior art by proposing, at a lower cost, a method for accurately assessing a state of charge of a battery taking into consideration the imbalance of the cells. In particular, the object of the invention is to provide a method in which the maximum amount of energy stored is constant on the whole so as to prevent the user from finding himself in an uncomfortable situation preventing him from assessing whether the remaining autonomy of the vehicle is sufficient to complete his journey. A further objective targeted here is to adjust the range of use of state of charge of each cell by taking into consideration the state of health of the cell, in particular the state of aging thereof. Lastly, the present invention aims to propose a method for assessing a state of charge of a battery on the basis of assessments of state of charge of the cells or of the battery in order to limit the number of processors necessary for carrying out this method.

The proposed solution is that the method for assessing a state of charge of a battery comprising a plurality of electrochemical cells connected in series, each of the cells having a state of charge held between a minimum allowable state of charge value and a maximum allowable state of charge value, comprises the following steps:
a step of determining, at a given moment, the minimum cell voltage and the maximum cell voltage from the voltages at the terminals of the cells,
a step of calculating a minimum state of charge of the cell having the minimum cell voltage and a maximum state of charge of the cell having the maximum cell voltage, the state of charge of the battery being between said minimum state of charge and said maximum state of charge,
a step of adjusting said minimum allowable state of charge value and said maximum allowable state of charge value of each cell depending on at least one physical quantity representative of a state of health of the cell and/or depending on the temperature of the battery.

This solution makes it possible overcome the aforementioned problems.

More precisely, the adjustment of the minimum allowable state of charge value and of said maximum allowable state of charge value of each cell depending on a physical quantity representative of a state of health of the cell makes it possible to take into consideration the state of health of each cell so as to sensibly choose a range of use of state of charge minimizing the uncertainties of assessment of the state of charge of the battery comprising said cells. This approach makes it possible to assess more reliably the remaining autonomy of the battery used conventionally in an electric or hybrid vehicle. The dependency of the ranges of use of state of charge of the cells on the respective states of health of said cells makes it possible to preserve a substantially constant maximum amount of stored energy of the battery. in addition, this method makes it possible to adjust the minimum and maximum states of charge of the battery depending on the state of health of each cell, moreover with use of minimal equipment. By way of example, a current sensor placed in series with the cells, a sensor for measuring the temperature of the battery, an electronic component able to measure solely the minimum cell voltage and maximum cell voltage, and a system for managing the state of charge of the battery collecting the current measurement taken by the current sensor, the temperature measurement taken by the temperature sensor, and the minimum cell voltage measurement and the maximum cell voltage measurement, make it possible to arrive at this result with few computing resources.

In one embodiment the method comprises at least one step including:
adjusting the state of charge of the battery to the minimum state of charge value when the minimum state of charge of the cell having the minimum cell voltage is strictly lower than the minimum allowable state of charge value of said cell, and/or
adjusting the state of charge of the battery to the maximum state of charge value when the maximum state of charge of the cell having the maximum cell voltage is strictly greater than the maximum allowable state of charge value of said cell.

In another embodiment, when the maximum state of charge of the cell having the maximum cell voltage is less than or equal to the maximum allowable state of charge value of said cell and the minimum state of charge of the cell having the minimum cell voltage is greater than or equal to the minimum allowable state of charge value of said cell, the assessment method comprises a step including assessing the state of charge (SOC_{pack}) of the battery, at a given moment k, by means of the relationship:

$${SOC}_{pack} ( k ) = \frac{{SOC}_{m i n} ( k ) - {BSOC}_{m i n} ( k )}{( {BSOC}_{ma x} ( k ) - {SOC}_{ma x} ( k ) ) + ( {SOC}_{m i n} ( k ) - {BSOC}_{m i n } ( k ) )} \times ( {BSOC}_{ma x} ( k ) - {BSOC}_{m i n} ( k ) ) + {BSOC}_{m i n} ( k )$$

In one embodiment of the invention, when the maximum state of charge of the cell having the maximum cell voltage is strictly greater than the maximum allowable state of charge value of said cell and the minimum state of charge of the cell having the minimum cell voltage is strictly lower than the minimum allowable state of charge value of this cell, the method comprises a step including attributing the “unavailable” value to the state of charge of the battery.

In one embodiment said at least one physical quantity representative of a state of health of the cell is a voltage measured at the terminals of this cell and/or a current passing through the cell and/or a temperature associated with the cell.

In one embodiment the correspondence between the minimum and maximum allowable state of charge values and said at least one physical quantity representative of the state of health of the cell is predetermined, preferably in a value table.

In one embodiment:
the range of use defined between the minimum allowable state of charge value and the maximum allowable state of charge value is such that it becomes broader depending on the state of health of the cell and the progression of aging thereof, and/or
said range of use is such that it is limited when the temperature of the battery is relatively low and below a predetermined temperature threshold.

A second subject of the invention is also targeted, in which a system for assessing a state of charge of a battery comprising a plurality of electrochemical cells connected in series, each of the cells having a state of charge to be held between a minimum allowable state of charge value and a maximum allowable state of charge value, comprises:
a current sensor able to provide a measurement of the current of the battery,
one or more temperature sensors able to provide a measurement of the temperature of the battery,
an electronic control unit able to collect the minimum cell voltage and the maximum cell voltage from the voltages at the terminals of the cells, the electronic control unit comprising a second assessment module able to assess the minimum state of charge of the cell by means of the minimum cell voltage, the current measurement, and the temperature measurement of the battery, a third assessment module able to assess the maximum state of charge of the cell by means of the maximum cell voltage, the current measurement, and the temperature measurement of the battery, a fifth assessment module able to determine the state of charge depending on the minimum state of charge and the maximum state of charge, and depending on the minimum allowable state of charge value and the maximum allowable state of charge value determined by a fourth module able to adjust said minimum allowable state of charge value and said maximum allowable state of charge value of each cell depending on at least one physical quantity representative of a state of health of the cell and/or depending on the temperature of the battery.

In one embodiment the system comprises a first module able to deliver directly to the electronic control unit solely the minimum cell voltage and the maximum cell voltage.

In accordance with a third subject, a vehicle comprising an assessment system according to any one of the above-mentioned embodiments is also targeted.

### BRIEF DESCRIPTION OF THE FIGURES

FIG. 1 shows a method for assessing a state of charge of a battery in accordance with a previous technique in which there is a first situation in which the battery is in a starting state, a second situation in which the battery is fully charged, and a third situation in which the battery is completely discharged. It is shown here that the range of use of state of charge of the battery is set by the cell charged to the greatest extent or by the cell charged to the lowest extent, due to the use constraints specific to the cells, which must remain, within a given voltage and state of charge range in order to avoid any risk of fire or premature degradation. For each of the situations shown, the actual range of use is 96%.

FIG. 2 shows a graph illustrating the progression of the minimum state of charge (SOC mm) of the cell having the minimum cell voltage, of the maximum state of charge (SOC_max) of the cell having the maximum cell voltage, and of the state of charge (SOC_pack) of the battery comprised between the minimum state of charge and the maximum state of charge, as a function of time, during a phase of discharge of the battery, for a range of use of state of charge of the cells between 0% and 100%, in accordance with a previous assessment method.

FIG. 3 shows a graph similar to the graph in FIG. 2 for a range of use of state of charge of the cells between 20% and 80%, in accordance with a previous method.

FIG. 4 shows a graph similar to the graph in FIG. 2 for the same range of use of state of charge of the cells between 20% and 80% for a method according to the invention. The circles in FIG. 2 show the correspondence between the minimum and maximum states of charge of the cells and the state of charge of the battery when the battery has a state of charge of 20% or 80%.

FIG. 5 shows a graph similar to the graph in FIG. 4 for a range of use of state of charge of the cells between 30% and 70% for a method according to the invention.

FIG. 6 shows a basic diagram of the system comprising means for carrying out the method according to the invention.

### DESCRIPTION OF EXEMPLARY EMBODIMENTS OF THE INVENTION

Hereinafter, a battery comprising N electrochemical cells C₁ to C_{N} connected in series will be considered. During operation, the same current I_{BAT} thus passes through the N cells, and the voltage U_{BAT} at the terminals of the battery corresponds at all times to the sum of the N voltages U₁ to U_{N} taken at the terminals of the N cells.

In accordance with the invention, the assessment of the state of charge of the battery is obtained on the basis of two particular values of the N cell voltages at a given moment, one corresponding to the minimum value over all the cell voltages, referred to as the minimum cell voltage, the other corresponding to the maximum value over all the cell voltages, referred to as the maximum cell voltage, these two values being denoted, respectively, as U_{Cmin} and U_{Cmax}. Each of the cells C₁ to C_{N} has a state of charge SOC within a range of use of state of charge comprising a minimum allowable state of charge value BSOCₘᵢₙ and a maximum allowable state of charge value BSOCₘₐₓ; the operation of the cells in this range of use makes it possible to protect them against potential degradation.

It is indeed possible to define a physical quantity on which the state of charge SOC_{pack} of the battery is directly or indirectly dependent, this physical quantity being dependent itself analytically, directly or indirectly, on the minimum state of charge SOCₘᵢₙ and the maximum state of charge SOCₘₐₓ in accordance with an equation including weighting elements which assure that the weight associated with the maximum state of charge SOC increases when the state of charge of the associated cell increases, and the weight associated with the minimum state of charge SOCₘᵢₙ increases when the state of charge of the associated cell decreases. Thus, the minimum cell voltage U_{Cmin} and the maximum cell voltage U_{Cmax} are first determined, at a given moment, from the voltages at the terminals of the cells. A minimum state of charge SOCₘᵢₙ of the cell having the minimum cell voltage U_{Cmin} and a maximum state of charge SOCₘₐₓ of the cell having the maximum cell voltage U_{Cmax} are then calculated, the state of charge SOC_{pack} of the battery being between said minimum state of charge SOCₘᵢₙ and said maximum state of charge SOCₘₐₓ.

The invention aims to ensure that the weight associated with the maximum state of charge SOCₘₐₓ is maximum when this state of charge is in the vicinity of a predetermined maximum use threshold corresponding to the maximum allowable state of charge value BSOCₘₐₓ of the associated cell, and the weight associated with the minimum state of charge SOCₘᵢₙ is maximum when this state of charge SOCₘᵢₙ is in the vicinity of a predetermined minimum use threshold corresponding to the minimum allowable state of charge value BSOCₘₐₓ of the associated cell. Between the two, the variation of the physical quantity must be continuous and without sudden variations. After the step of calculation making it possible to determine the minimum state of charge SOCₘᵢₙ by means of the minimum cell voltage U_{Cmin} and the maximum state of charge SOCₘₐₓ by means of the maximum cell voltage U_{Cmax}, it is then possible to adjust the state of charge of the battery pack SOC_{pack} depending on the minimum and maximum states of charge SOCₘᵢₙ and SOCₘₐₓ, said minimum allowable state of charge value BSOCₘᵢₙ and said maximum allowable state of charge value BSOCₘₐₓ.

In accordance with the invention, said minimum allowable state of charge value BSOCₘᵢₙ and said maximum allowable state of charge value BSOCₘₐₓ of each cell are variable. More precisely, these values BSOCₘᵢₙ and BSOCₘₐₓ are adjusted depending on at least one physical quantity representative of a state of health of the cell and/or depending on the temperature T_{BAT} of the battery. This state of health of the cell in fact defines the state of aging of the cell.

A basic diagram of an assessment system comprising means for carrying out the method according to the invention is shown in FIG. 6. The assessment system comprises a first module 10 connected to each terminal of the cells C₁ . . . C_{N} forming the battery, able to deliver the minimum cell voltage U_{Cmin} and maximum cell voltage U_{Cmax}. The first module 10 is preferably a component able to perform the function MIN-MAX, i.e. able to determine and deliver, directly to an electronic control unit ECU, the minimum cell voltage U_{Cmin} and the maximum cell voltage U_{Cmax} without any need to measure the N cell voltages. This first module 10 can be an analog or software component. The first module 10 is preferably capable of identifying the two cells which have the values U_{Cmin} and U_{Cmax}, making it possible to have a method which is still as precise, but requires less computational power.

The system also comprises a current sensor (not shown) able to provide a measurement I_{BAT} of the current of the battery and one or more temperature sensors (not shown) able to provide one or more measurements T_{BAT} of the temperature of the battery.

Typically, the electronic control unit ECU therefore collects the current measurement I_{BAT}, the temperature measurement T_{BAT} of the battery, and therefore the minimum cell voltage U_{Cmin} and the maximum cell voltage U_{Cmax}. The electronic control unit ECU calculates, by means of a second assessment module 20, the minimum state of charge SOCₘᵢₙ of the cell on the basis of the minimum cell voltage U_{Cmin} the current measurement I_{BAT} and the temperature measurement T_{BAT} of the battery. A third assessment module 30 calculates the maximum state of charge SOCₘₐₓ of the cell on the basis of the maximum cell voltage U_{Cmax}, the current measurement I_{BAT} and the temperature measurement T_{BAT} of the battery. These second and third assessment modules 20, 30 calculate assessments of the state of charge of the cell SOCₘᵢₙ, SOCₘₐₓ respectively, on the basis of the three values. The maximum state of charge SOC. and the minimum state of charge SOCₘᵢₙ are typically assessed by integration of the current I_{BAT} of the battery, by Kalman filtering, or by any other method known to a person skilled in the art.

A fourth computing module 40, preferably in the electronic control unit ECU, receives information relating to the state of health of the cells, in particular the state of aging thereof. The physical quantities entering this fourth computing module 40 are the cell voltage, the current measurement I_{BAT}, the temperature measurement T_{BAT} of the battery, the discharge time of the cell, the maximum capacity of the battery pack, the assessment of the increase of internal resistance of the battery, or any other quantity characteristic of the aging of the cells and the battery pack. The calculation of the minimum allowable state of charge value BSOCₘᵢₙ and of said maximum allowable state of charge value BSOCₘₐₓ by the fourth module 40 can be further refined by taking into account the temperature in the vicinity of the two identified cells, and by using the maximum capacity thereof.

On the basis of at least one of these physical quantities, this fourth module 40 adjusts the minimum allowable state of charge value BSOCₘᵢₙ and said maximum allowable state of charge value BSOCₘₐₓ defining the range of use of the cells, which makes it possible to take into consideration the state of aging of the cell. An arrangement of this type helps to preserve a maximum quantity of usable energy of the battery at a substantially constant level.

In one embodiment the range of use defined between the minimum allowable state of charge value BSOCₘᵢₙ and the maximum allowable state of charge value BSOCₘₐₓ is such that it becomes broader depending on the state of health of the cell and the progression of aging thereof. In another embodiment said range of use is such that it is limited when the temperature of the battery is relatively low and below a predetermined temperature threshold, depending on the characteristics relating to performance and/or aging of the electrochemical cells forming the battery in cold conditions, for example 0° C. It is the fourth module 40 which processes this information in order to modify the range of use

A fifth assessment module 50, in the electronic control unit ECU, receives, on the one hand, the assessments of the minimum state of charge SOCₘᵢₙ and of the maximum state of charge SOCₘₐₓ provided by said second and third assessment modules 20, 30, and, on the other hand, the minimum allowable state of charge value BSOCₘᵢₙ and the maximum allowable state of charge value BSOCₘₐₓ, and calculates an assessment of the state of charge of the battery SOC_{pack} on the basis of these values. One function of this fifth assessment module 50 is to weight the values SOCₘᵢₙ, SOCₘₐₓ depending on the signals BSOCₘᵢₙ and BSOCₘₐₓ (which define the range of use in SOC of each of the cells) so as to give greater weight to the information SOCₘₐₓ when a cell approaches the maximum value BSOCₘₐₓ, and, in the reverse case, to give greater weight to the information SOCₘᵢₙ when a cell approaches the minimum value BSOCₘᵢₙ. Between these two extreme cases, the state of charge SOC_{pack} of the battery must have continuous behavior, without sudden changes to its value, limited by the values SOCₘᵢₙ, and SOCₘₐₓ of the cells. Beyond the nominal range of use, that is to say when the cell charged to the lowest extent reaches a state of charge SOC lower than BSOCₘᵢₙ or when the cell charged to the greatest extent reaches a state SOC greater than BSOCₘₐₓ, the state of charge SOC_{pack} of the battery must follow the variation of the most limiting cell (i.e. SOCₘᵢₙ or SOCₘₐₓ respectively).

To arrive at this result, the fifth module 50 implements an algorithm.

In a number of cases:
If SOCₘᵢₙ≧BSOCₘᵢₙ and SOCₘₐₓ≦BSOCₘₐₓ, the following formula is applied:

$${SOC}_{pack} ( k ) = \frac{{SOC}_{m i n} ( k ) - {BSOC}_{m i n} ( k )}{( {BSOC}_{ma x} ( k ) - {SOC}_{ma x} ( k ) ) + ( {SOC}_{m i n} ( k ) - {BSOC}_{m i n } ( k ) )} \times ( {BSOC}_{ma x} ( k ) - {BSOC}_{m i n} ( k ) ) + {BSOC}_{m i n} ( k )$$

in which SOCₘᵢₙ, SOCₘₐₓ, BSOCₘᵢₙ and BSOCₘₐₓ are, respectively, sampled values, at the discrete moment k, of the minimum state of charge, of the maximum state of charge, of the minimum allowable state of charge value BSOCₘᵢₙ, and of the maximum allowable state of charge value BSOCₘₐₓ.
If SOCₘᵢₙ<BSOCₘᵢₙ and SOCₘₐₓ≦BSOCₘₐₓ, then the following relationship is applied:

SOC_{pack}(k)=SOCₘᵢₙ(k)
If SOCₘᵢₙ≧SOCₘᵢₙ and SOCₘₐₓ>BSOCₘₐₓ, then the following relationship is applied:

SOC_{pack}(k)=SOCₘₐₓ(k)
If SOCₘᵢₙ<BSOCₘᵢₙ and SOCₘₐₓ>BSOCₘₐₓ, then the state of charge SOC_{pack} of the battery is considered to be unavailable. The battery is said to be imbalanced because the cell charged to the greatest extent has exceeded the maximum allowable state of charge value BSOCₘₐₓ whereas the cell charged to the lowest extent is below the minimum allowable state of charge value BSOCₘᵢₙ. A battery of this type is in fact unusable and requires rebalancing at the least.

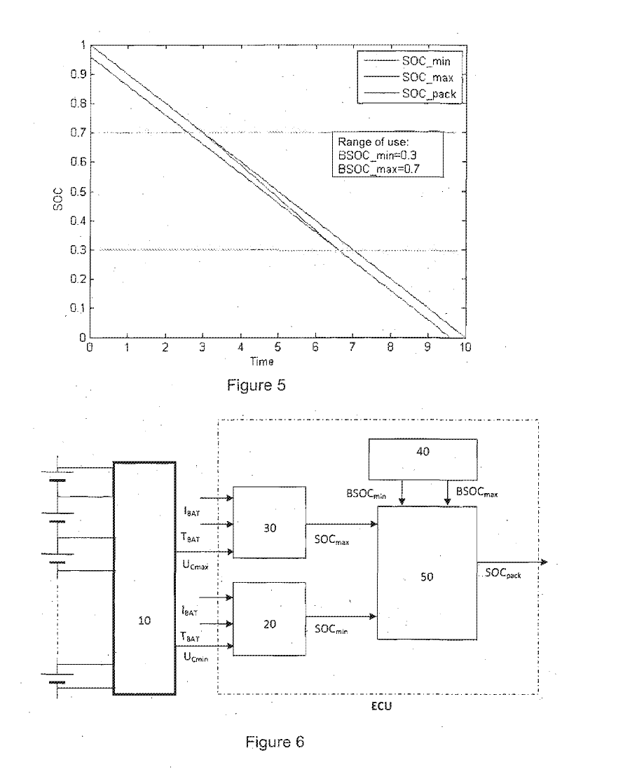

The use of an algorithm of this type for assessing the state of charge SOC_{pack} of the battery makes it possible to obtain the behaviors described in FIGS. 4 and 5 for two different values of BSOCₘᵢₙ and BSOCₘₐₓ: the SOC_{pack} varies continuously between SOCₘᵢₙ and SOCₘₐₓ and tends toward the value SOCₘᵢₙwhen this approaches BSOCₘᵢₙ, and toward SOCₘₐₓ when this approaches BSOCₘₐₓ. Beyond the nominal zone, SOC_{pack} is equal either to SOCₘᵢₙ (when SOCₘᵢₙ<BSOCₘᵢₙ) or to SOCₘₐₓ (when SOCₘₐₓ>BSOCₘₐₓ).

FIG. 4 shows the result of an assessment of the state of charge SOC_{pack} of the battery in a range of use between a value BSOCₘᵢₙ equal to 0.2 and a value BSOCₘₐₓ equal to 0.8. It is noted with the assessment method and/or system according to the invention that the state of charge SOC_{pack} of the battery follows the minimum state of charge SOCₘᵢₙ for values lower than or equal to 0.2 and the maximum state of charge SOCₘₐₓ for values greater than or equal to 0.8. The state of charge SOC_{pack} of the battery adapts automatically to the range of use, which can be modified depending on the state of health of the cells.

FIG. 5 shows a result of a comparable assessment of the state of charge SOC_{pack} of the battery over a range between a value BSOCₘᵢₙ equal to 0.3 and a value BSOCₘₐₓ equal to 0.7. The behavior of the state of charge SOC_{pack} of the battery corresponds to that anticipated, the assessment adapting automatically to the modified range of use.

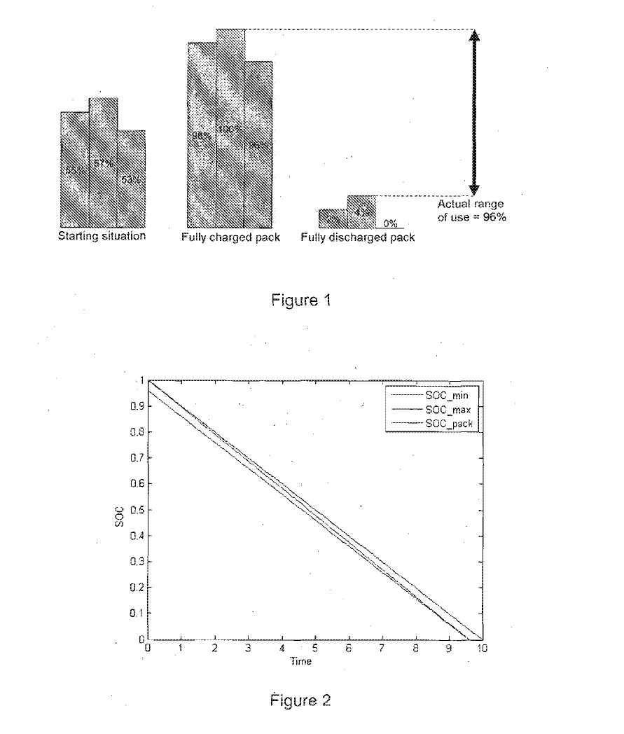

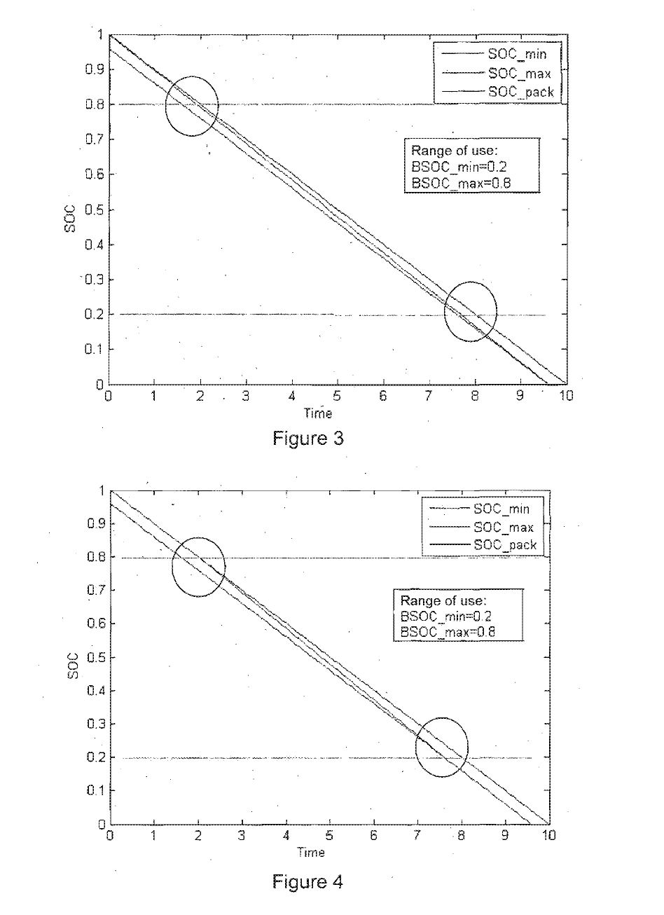

By comparing with prior-art methods, of which the results are shown in FIGS. 2 and 3, the assessment of the state of charge SOC_{pack} of the battery is not satisfactory here. In fact, when the state of charge of the battery SOCₘᵢₙ of the cell charged to the lowest extent reaches 0.2 (that is to say the minimum allowable state of charge value BSOCₘᵢₙ), the state of charge SOC_{pack} of the battery is strictly greater than 0.2. Likewise, when the state of charge of the battery SOCₘₐₓ of the cell charged to the greatest extent reaches 0.8, the state of charge SOC_{pack} of the battery is strictly lower than 0.8. In this prior-art method, these ranges of use are not taken into consideration. As a result, this method does not take into consideration the state of health of the cells or the progression of their state of aging over the course of time.

1-10. (canceled)

11. A method for assessing a state of charge of a battery comprising a plurality of electrochemical cells connected in series, each of the cells having a state of charge held between a minimum allowable state of charge value and a maximum allowable state of charge value, said method comprising:
determining, at a given moment, the minimum cell voltage and the maximum cell voltage from the voltages at terminals of the cells;
calculating a minimum state of charge of the cell having the minimum cell voltage and a maximum state of charge of the cell having the maximum cell voltage, the state of charge of the battery being between said minimum state of charge and said maximum state of charge; and
adjusting said minimum allowable state of charge value and said maximum allowable e of charge value of each cell depending on at least one physical quantity representative of a state of health of the cell and/or depending on a temperature of the battery.

12. The assessment method as claimed in claim 11, further comprising:
adjusting the state of charge of the battery to the minimum state of charge value when the minimum state of charge of the cell having the minimum cell voltage is strictly lower than the minimum allowable state of charge value of said cell, and/or
adjusting the state of charge of the battery to the maximum state of charge value when the maximum state of charge of the cell having the maximum cell voltage is strictly greater than the maximum allowable state of charge value of said cell.

13. The assessment method as claimed in claim 11, wherein, when the maximum state of charge of the cell having the maximum cell voltage is less than or equal to the maximum allowable state of charge value of said cell and the minimum state of charge of the cell having the minimum cell voltage is greater than or equal to the minimum allowable state of charge value of said cell, the assessment method comprises a step including assessing the state of charge of the battery, at a given moment k, by means of the relationship:
$${SOC}_{pack} ( k ) = \frac{{SOC}_{m i n} ( k ) - {BSOC}_{m i n} ( k )}{( {BSOC}_{ma x} ( k ) - {SOC}_{ma x} ( k ) ) + ( {SOC}_{m i n} ( k ) - {BSOC}_{m i n} ( k ) )} \times ( {BSOC}_{m ax} ( k ) - {BSOC}_{m i n} ( k ) ) + {BSOC}_{m i n} ( k ) ,$$
with SOC_{pack} being the state of charge of the battery,
SOCₘᵢₙ being the minimum state of charge of the cell having the minimum cell voltage,
SOCₘₐₓ being the maximum state of charge of the cell having the maximum cell voltage,
BSOCₘᵢₙ being t le minimum allowable state of charge value,
BSOCₘₐₓ being the maximum allowable state of charge value, and k being the given moment.

14. The assessment method as claimed in claim 11, wherein, when the maximum state of charge of the cell having the maximum cell voltage is strictly greater than the maximum allowable state of charge value of said cell and the minimum state of charge of the cell having the minimum cell voltage is strictly lower than the minimum allowable state of charge value of said cell, the method further comprises:
attributing an unavailable value to the state of charge of the battery.

15. The assessment method as claimed in claim 11, wherein said at least one physical quantity representative of a state of health of the cell is a voltage measured at the terminals of the cell and/or a current passing through the cell and/or a temperature associated with the cell.

16. The assessment method as claimed in claim 11, wherein a correspondence between the minimum and maximum allowable state of charge values and said at least one physical quantity representative of the state of health of the cell is predetermined.

17. The assessment method as claimed in claim 16, wherein the correspondence is predetermined in a value table.

18. The assessment method as claimed in claim 14, wherein.
a range of use defined between the minimum allowable state of charge value and the maximum allowable state of charge value is such that the range becomes broader depending on the state of health of the cell and a progression of aging thereof, and/or
said range of use is such that the range is limited when the temperature of the battery is relatively low and below a predetermined temperature threshold.

19. A system for assessing a state of charge of a battery comprising a plurality of electrochemical cells connected in series, each of the cells having a state of charge to be held between a minimum allowable state of charge value and a maximum allowable state of charge value, said system comprising:
a current sensor configured to provide a measurement of a current of the battery;
one or more temperature sensors configured to provide a measurement of a temperature of the battery; and
an electronic control unit configured to collect a minimum cell voltage and a maximum cell voltage from voltages at terminals of the cells, the electronic control unit comprising a second assessment module configured to assess a minimum state of charge of the cell by the minimum cell voltage, the current measurement, and the temperature measurement of the battery, a third assessment module configured to assess a maximum state of charge of the cell by the maximum cell voltage, the current measurement, and the temperature measurement of the battery, a fifth assessment module configured to determine the state of charge of the battery depending on the minimum state of charge and the maximum state of charge, and depending on the minimum allowable state of charge value and the maximum allowable state of charge value determined by a fourth module configured to adjust said minimum allowable state of charge value and said maximum allowable state of charge value of each cell depending on at least one physical quantity representative of a state of health of the cell and/or depending on the temperature of the battery.

20. The assessment system as claimed in claim 19, further comprising a first module configured to deliver directly to the electronic control unit solely the minimum cell voltage and the maximum cell voltage.

21. A vehicle, comprising:
the assessment system as claimed in claim 19.
